(19) United States
(12) Patent Application Publication
(10) Pub. No.: US 2008/0258837 A1
(43) Pub. Date: Oct. 23, 2008

(54) BALUN SIGNAL TRANSFORMER

(75) Inventors: Lianjun Liu, Chandler, AZ (US); Qiang Li, Gilbert, AZ (US)

Correspondence Address: MESCHKOW & GRESHAM, P.L.C., 5727 NORTH SEVENTH STREET, SUITE 409, PHOENIX, AZ, 85014, US

(73) Assignee: FREESCALE SEMICONDUCTOR, INC., Austin, TX (US)

(21) Appl. No.: 11/737,270

(22) Filed: Apr. 19, 2007

(51) Int. Cl. H03H 7/42

(52) U.S. Cl. 333/25

(57) ABSTRACT

A system 20 includes an unbalanced device 22, a balanced device 24, and a balun (balanced-unbalanced) signal transformer 26 interposed between devices 22 and 24. The balun signal transformer 26 includes a balanced external port section 32 formed by ports 40 and 42. The balun signal transformer 26 includes a symmetric transformer 48 having a balanced port 50 formed by terminals 52 and 54. Terminal 52 is electrically interconnected with port 40, and an inductor 64 is interposed between terminal 54 and port 42. The inductor 64 shifts a phase of a signal component 72 at terminal 54 to balance substantially one hundred eighty degrees out-of-phase with a signal component 70 at terminal 52.

### TECHNICAL FIELD OF THE INVENTION

The present invention relates generally to balun signal transformers. More specifically, the present invention relates to a balun signal transformer that achieves high common mode rejection.

### BACKGROUND OF THE INVENTION

A balun (balanced-to-unbalanced) signal transformer is a passive electronic circuit that functions to convert an unbalanced signal (i.e., unbalanced in relation to ground) into balanced signals and vice versa of converting balanced signals into an unbalanced signal. A signal incoming to an unbalanced port of the balun transformer may be divided between two balanced ports of the balun transformer providing signals which have the same amplitude but phases differing by approximately one hundred and eighty degrees in relation to one another. Baluns may, for example, be used in transmitting circuits and receiving circuits of wireless and/or cable communications systems, for construction of balanced amplifiers, mixers, voltage controlled oscillators, antenna systems, and so forth.

In balun transformer design, important specifications to be taken into account are insertion loss and common mode rejection. Insertion loss is defined as the amount of signal loss occurring in the balun transformer. Common mode rejection is the phenomenon whereby a signal common to two lines, but opposite in polarity from one another, gets cancelled at its destination. In the balanced lines of a balun there is a positive signal on one cable and a negative or opposite polarity signal on the other. Thus, any signal common to both wires will eventually get cancelled at the receiving end. Accordingly, an effective balun transformer design should ideally have very low insertion loss and a large common mode rejection ratio.

Symmetric balun signal transformers have been developed. The symmetrical configuration of these balun signal transformers generally yields a well-behaved signal provided at the balanced ports that is generally equal in amplitude and opposite in polarity. Some design specifications call for the common mode rejection ratio (CMRR) to be “better” then −20 dB. The power of the signal common to two lines is significantly less than the input signal. Accordingly, the CMRR is sometimes represented as a negative number to indicate the lower power of the common signal relative to the input signal. As such, a “better” or high CMRR is one that is negative, but is large in magnitude, for example, -30dB. Unfortunately, even the symmetric baluns cannot meet the high common mode rejection requirements while concurrently satisfying low insertion low, microminiaturization, manufacturing repeatability, and low cost requirements. Accordingly, what is needed is a balun signal transformer characterized by high common mode rejection, low insertion loss, and in which size and cost are kept low.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a block diagram of a system for transforming a signal in accordance with one embodiment of the present invention;

FIG. 2 shows an embodiment of a circuit schematic for balun signal transformer incorporated within the system of FIG. 1;

FIG. 3 shows a top plan view of the balun signal transformer; and

FIG. 4 shows a chart of exemplary electrical characteristics of the balun signal transformer.

### DETAILED DESCRIPTION

A system for transforming signals includes a balun (balanced-to-unbalanced) signal transformer interposed between an unbalanced device and a balanced device. The balun signal transformer includes a symmetric transformer having a balanced port and an unbalanced port. An inductor is connected to one of a pair of terminals of the balanced port to adjust the phase between signals at a pair of terminals of the balanced port, thereby improving common mode rejection. The balun may be readily and cost effectively formed on a substrate as an integrated passive device.

FIG. 1 shows a block diagram of a system 20 for transforming a signal in accordance with one embodiment of the present invention. System 20 includes an unbalanced device 22, a balanced device 24, and a balun signal transformer 26 interposed between unbalanced device 22 and balanced device 24. Unbalanced device 22 may be any of a number of devices or components that provides a single ended output signal or receives a single ended input signal. Balanced device 24 may be any of a number of devices or components that receives a differential input signal or provides a differential output signal. System 20 may be formed on a common substrate 28 as an integrated circuit. Alternatively, unbalanced device 22, balanced device 24, and balun signal transformer 26 may be formed utilizing a combination of discrete components and/or as integrated circuits on discrete substrates. Additional, different, or fewer components may be provided.

Balun signal transformer 26 includes an unbalanced external port section 30 and a balanced external port section 32. Unbalanced external port section 30 includes a pair of unbalanced terminals 34 and 36. In one embodiment, terminal 34 is connected to a single ended port 38 of unbalanced device 22 and terminal 36 may be terminated as ground. External balanced port section 32 includes a pair of balanced ports 40 and 42 and balanced device 24 includes a corresponding pair of differential ports 44 and 46. In one embodiment, port 40 is connected to differential port 44 and port 42 is connected to differential port 46. The term “external” in connection with port sections 30 and 32 is utilized herein to refer to input/output sections that convey signals to and from balun signal transformer 26.

Substrate 28 may be silicon, gallium arsenide (GaAs), combinations thereof, or other known or upcoming semiconductor materials. Substrate 28 may be used with an integrated passive device process, complementary metal-oxide semiconductor (CMOS) integrated circuit process, or other semiconductor processes for forming system 20 on a chip. Substrate 28 defines a circuit plane where etching, deposition, or other techniques are used to form system 20. Although balun signal transformer 26 is described as being formed on a substrate utilizing a semiconductor process technology, in other embodiments, balun signal transformer 26 may be implemented utilizing a combination of discrete passive components.

Balun signal transformer 26 provides coupling between unbalanced device 22 and balanced device 24. More specifically, balun signal transformer 26 may be used for conversion between an unbalanced input signal from unbalanced device 22 to a balanced output signal conveyed to balanced device 24. Additionally, balun signal transformer 26 may be used for conversion between a balanced input signal from balanced device 24 to an unbalanced output signal conveyed to unbalanced device 22.

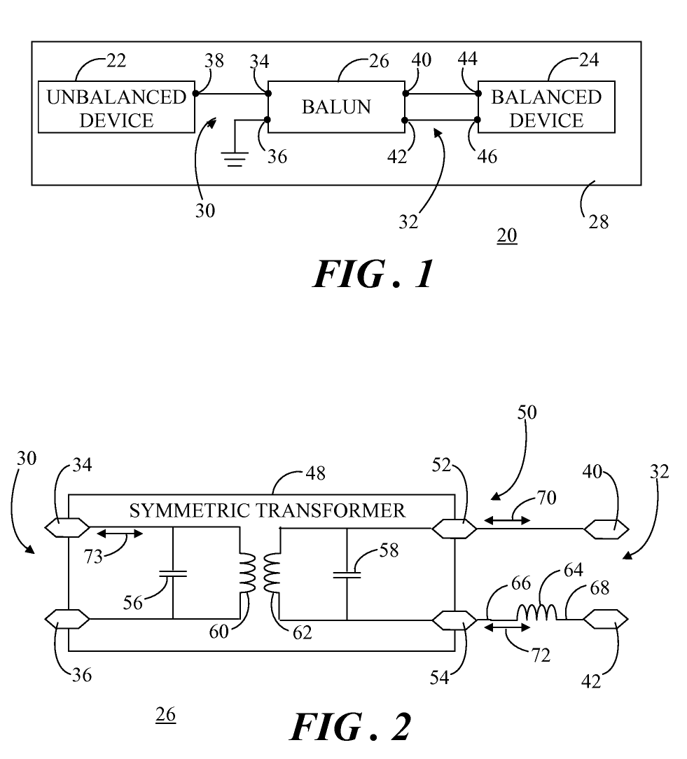

FIG. 2 shows an embodiment of a circuit schematic for balun signal transformer 26 incorporated within system 20 (FIG. 1). Balun signal transformer 26 includes a symmetric transformer, or symmetric balun, 48 having unbalanced terminals 34 and 36 that make up unbalanced external port section 30. Symmetric transformer 48 further includes a balanced port 50 formed by terminals 52 and 54. In addition, symmetric transformer 48 includes a tuning capacitor 56 interposed between unbalanced terminals 34 and 36, and a tuning capacitor 58 interposed between terminals 52 and 54.

Symmetric transformer 48 includes two or more windings, coils, or folds 60, 62. Terminals 34 and 36 of unbalanced port 30 are formed at opposing ends of winding 60. Terminals 52 and 54 of balanced port 50 are formed at opposing ends of winding 62. In addition, terminal 52 is connected to port 40 of balanced external port section 32. In accordance with an embodiment, balun signal transformer 26 further includes an inductor 64 having opposing ends 66, 68. Terminal 54 of port 50 is connected to end 66 of inductor 64. End 68 of inductor 64 is connected to port 42 of balanced external port section 32.

In general, symmetric balun structures (e.g., symmetric transformer 48) provide for more constant phase response, or balanced signals, between the terminals of the balanced port (e.g., terminals 52 and 54 of balanced port 50) than their asymmetric counterparts. However, when common mode rejection requirements are high, for example, better than −20 dB, the symmetric design still may not be suitable. That is, a signal common to both balanced terminals of the symmetric balun may not be effectively canceled due to a phase difference, or shift, between the two signal components.

Inductor 64 is interposed between terminal 54 of balanced port 50 of symmetric transformer 48 and port 42 of balanced external port section 32 to adjust the phase balance between a signal component, represented by a bidirectional arrow 70, at terminal 52 and a signal component, represented by a bidirectional arrow 72, at terminal 54. As such, inductor 64 with the appropriate impedance transformation ratio causes the phase of signal component 72 to shift so that signal component 72 is substantially one hundred eighty degrees out-of-phase from signal component 70. Accordingly, use of inductor 64 tunes the phase unbalance of the signal components 70 and 72 at terminals 52 and 54 so that the signal components 70 and 72 at balanced ports 40 and 42 of external port section 32 are largely balanced. This situation results in improved common mode rejection.

By way of illustration, when unbalanced external port section 30 serves as input from unbalanced device 22 (FIG. 1) and balanced external port section 32 serves as output to balanced device 24 (FIG. 1), a method of transforming a signal, represented by bidirectional arrow 73, from unbalanced device 22 entails transforming, or dividing the signal 73 with symmetric transformer 48 to form signal component 70 provided at terminal 52 and signal component 72 provided at terminal 54. A phase of signal component 72 is adjusted to balance with signal component 70 using inductor 64. Signal component 70 and phase shifted signal component 72 are output from ports 40 and 42 of balanced external port section 32 to balanced device 24 (FIG. 1).

By way of another illustration, when balanced external port section 32 serves as input from balanced device 24 and unbalanced external port section 30 serves as output to unbalanced device 22, a method of transforming a signal entails receiving the signal as first and second signal components 70 and 72 at ports 40 and 42. A phase of signal component 72 is adjusted to balance with signal 70 using inductor 64. Signal component 70 and phase shifted signal component 72 are input to symmetric transformer 48 where they are transformed to an output signal, i.e., signal 73. Signal 73 is subsequently output from symmetric transformer 48 to unbalanced device 22.

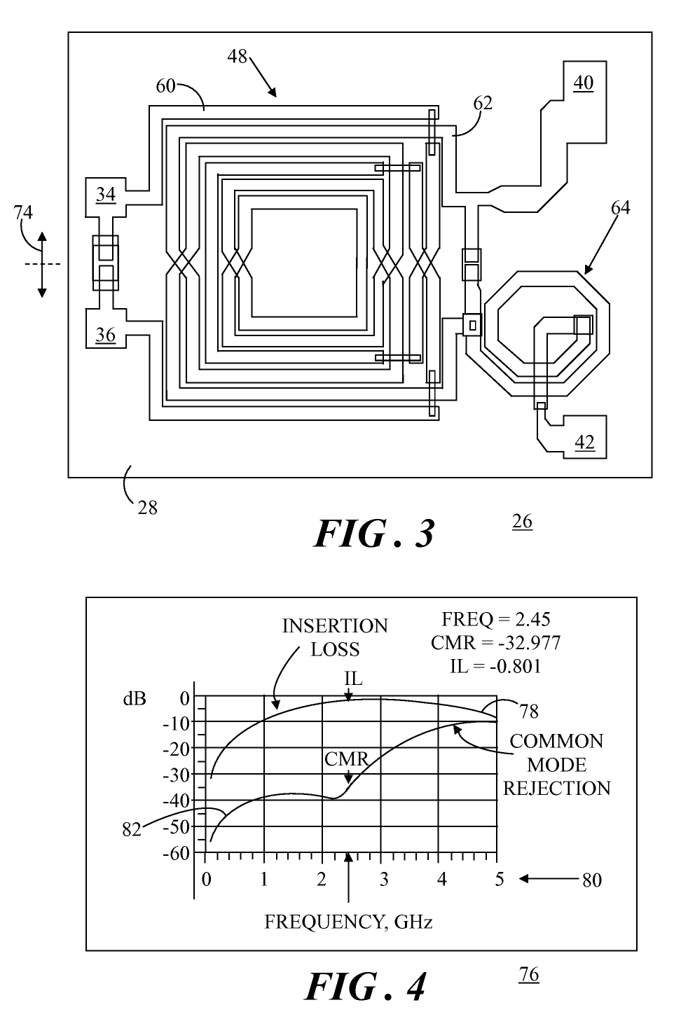

FIG. 3 shows a top plan view of the balun signal transformer 26 including symmetric transformer 48 and inductor 64. Balun signal transformer 26, implemented as an integrated circuit mounted on substrate 28, may be a stand alone device. Although in other embodiments, transformer 26 may be combined with other circuits on substrate 28 as mentioned above. In this example, balun signal transformer 26 has been produced utilizing an integrated passive device process technology. As used herein, an integrated passive device (IPD) is a passive electronic device or a passive electronic component that does not require a source of energy for its operation and that can be fabricated using semiconductor process technology. An IPD can be produced with very high precision, excellent reproducibility, and low cost in high quantities by utilizing semiconductor wafer processing technologies. Thus, a layout of balun signal transformer 26 represents an IPD realization, where all of the depicted elements are formed on a surface of substrate 28.

In the illustrated embodiment, terminals 34 and 36 of unbalanced external port section 30 (FIG. 1) are shown as pads that may interconnect with other components, such as unbalanced device 22 (FIG. 1) and ground, via bond wires (not shown). Similarly, ports 40 and 42 of balanced external port section 32 (FIG. 1) are shown as pads that may interconnect with other components, such as balanced device 24 (FIG. 1), via bond wires. In this example, winding 60 is an input having a trace arranged on substrate 28 that forms two turns and winding 62 is an output having a trace arranged on substrate 28 that forms four turns. Accordingly, symmetric transformer 48 may produce an impedance transformation of one to four, for example, from fifty ohms to two hundred ohms.

Windings 60 and 62 are symmetrically arranged on substrate 28. This symmetry is represented by a bidirectional arrow 74 indicating a top half of symmetric transformer 48 is symmetric, or identical, to a bottom half of symmetric transformer 48. Inductor 64 is a winding, or coil, also formed on substrate 28. Inclusion of inductor 64 results in an asymmetric configuration of balun signal transformer 26. However, this asymmetry functions to adjust the phase balance between the signals at ports 40 and 42, and therefore improves common mode rejection, or cancellation of any signal common to both of terminals 52 and 54 (FIG. 2).

FIG. 4 shows a chart 76 of exemplary electrical characteristics of balun signal transformer 26. Chart 76 includes an insertion loss curve 78, in decibels, relative to frequency 80. Chart 76 further includes a common mode rejection curve 82, in decibels, relative to frequency 80. Simulations reveal that with the inclusion of inductor 64 (FIG. 2) at one of the balanced terminals 54 (FIG. 2), insertion loss, IL may be low, for example, approximately 0.8 db, and common mode rejection, CMR, may be high, for example, approximately −33 dB at a frequency of 2.45 GHz.

An embodiment described herein comprises a balun signal transformer that includes a symmetric transformer having an additional inductor connected to one of a pair of balanced terminals of the symmetric transformer. The inductor functions to adjust the phase balance between the signals at the balanced terminals to achieve better common mode rejection than a conventional symmetric signal transformer while maintaining low insertion loss. The symmetric transformer and the inductor may be implemented as an integrated circuit formed on a substrate utilizing an integrated passive device process technology to achieve small size, manufacturing repeatability, and low cost, without sacrificing performance.

Although the preferred embodiments of the invention have been illustrated and described in detail, it will be readily apparent to those skilled in the art that various modifications may be made therein without departing from the spirit of the invention or from the scope of the appended claims.

What is claimed is:

1. A balanced-unbalanced (balun) signal transformer comprising:
a symmetric transformer having an unbalanced port and a balanced port, said balanced port being formed by first and second terminals; and
an inductor connected to said second terminal, said inductor shifting a phase of a second signal at said second terminal to balance with a first signal at said first terminal.

2. A balun signal transformer as claimed in claim 1 wherein said second signal shifted by said inductor is substantially one hundred eighty degrees out-of-phase from said first signal.

3. A balun signal transformer as claimed in claim 1 further comprising a substrate, and said symmetric transformer and said inductor are implemented as an integrated circuit formed on said substrate.

4. A balun signal transformer as claimed in claim 1 wherein said symmetric transformer and said inductor are implemented with a combination of discrete passive components.

5. A balun signal transformer as claimed in claim 1 wherein said symmetric transformer comprises:
a first winding, said unbalanced port being formed by third and fourth terminals of said first winding; and
a second winding in communication with said first and second terminals.

6. A balun signal transformer as claimed in claim 1 wherein:
said balun signal transformer further comprises an external port; and
said inductor comprises a winding having a first end and a second end, said first end being connected to said second terminal, and said second end being connected to said external port.

7. A balun signal transformer as claimed in claim 6 wherein said external port is a first external port, and said balun signal transformer further comprises a second external port, said first terminal being connected to said second external port.

8. A balun signal transformer as claimed in claim 1 wherein said symmetric transformer further comprises:
a winding having said first and second terminals; and
a capacitor connected between said first and second terminals of said winding.

9. A system for transforming signals comprising:
a balanced device having first and second ports; and
a balun signal transformer, said balun signal transformer including:
a symmetric transformer having a balanced port, said balanced port being formed by first and second terminals, said first terminal being connected to said first port; and
an inductor having a first end connected to said second terminal and a second end connected to said second port, said inductor shifting a phase of a second signal at said second terminal to balance with a first signal at said first terminal.

10. A system as claimed in claim 9 further comprising a substrate, and said symmetric transformer and said inductor are implemented as an integrated circuit formed on said substrate.

11. A system as claimed in claim 10 wherein said balanced device is formed on said substrate.

12. A system as claimed in claim 9 wherein said symmetric transformer further comprises:
a winding having said first and second terminals; and
a capacitor connected between said first and second terminals of said winding.

13. A system as claimed in claim 9 wherein:
said system further comprises an unbalanced device having a third port; and
said symmetric transformer comprises a unbalanced port being formed by third and fourth terminals, said third terminal being connected to said third port.

14. A method of transforming a signal comprising:
transforming said signal with a symmetric balun transformer;
providing said signal as a first signal component at a first terminal of a balanced port of said symmetric balun transformer;
providing said signal as a second signal component at a second terminal of a balanced port of said symmetric balun transformer; and
adjusting a phase of said second signal component to balance with said first signal component using an inductor connected to said second terminal.

15. A method as claimed in claim 14 further comprising:
receiving said signal as an input signal at an unbalanced port of said symmetric balun transformer from an unbalanced device; and
outputting said first and signal components to a balanced device following said adjusting operation.

16. A method as claimed in claim 14 further comprising:
receiving said signal separated into said first and signal components from a balanced device;
performing said adjusting operation in response to said receiving operation and prior to providing said first and second signal components at respective ones of said first and second terminals;
performing said transforming operation to transform said signal separated into said first and second signal components to an output signal; and
outputting said output signal to an unbalanced device.
